(19) United States
(12) Patent Application Publication
(10) Pub. No.: US 2010/0235721 A1
(43) Pub. Date: Sep. 16, 2010

(54) Rate Matching and De-Rate Matching for an LTE Transport Channel

(75) Inventors: Moshe Bukris, Rishon Lezion (IL); Ido Gazit, Haifa (IL)

Correspondence Address: IP Legal Services, 1500 East Lancaster Avenue, Suite 200, P.O. Box 1027, Paoli, PA, 19301, US

(73) Assignee: LSI Corporation

(21) Appl. No.: 12/403,621

(22) Filed: Mar. 13, 2009

(51) Int. Cl. H03M 13/27; G06F 11/08

(52) U.S. Cl. 714/786; 714/E11.031

(57) ABSTRACT

Described embodiments provide for rate matching with an encoded sequence of data bits. The encoded sequence of data bits is divided into two or more sub-blocks, with each sub-block having at least one column of bits, each including a set of valid bits. A set of dummy bits is generated and appended to each column of each sub-block. A starting point index for the set of valid bits within each sub-block is generated and the number of bits supported by the physical layer is determined. Only the valid bits of each sub-block are interleaved, based on each starting point index, until either i) there are no valid bits remaining, or ii) the number of interleaved bits reaches the number of bits supported by the physical layer. All dummy bits and any valid bits exceeding the number of bits supported by the physical layer are omitted.

### BACKGROUND OF THE INVENTION

1. Field of the Invention

The present invention relates to generally to data transmission and reception in communication systems, and, more particularly, to rate matching and interleaving blocks of data in an LTE transport channel.

2. Description of the Related Art

Rate matching by interleaving is a commonly employed technique in telecommunication systems. Interleaving generally comprises receiving a block of data having a given block length, and rearranging the order of data values in the block. Interleaving may be employed, for example, to remove non-random sequences of values in a data stream, or may be employed to reduce effects of burst errors inserted into the block of data as the block of data passes through a transmission medium.

For example, interleaving is an important subprocess within rate matching in the Third Generation Partnership Project Long Term Evolution (“3GPP LTE”) transport channel. 3GPP LTE is a collaboration between telecommunications corporations and associations, to create a globally applicable third generation (“3G”) mobile phone system specification. The 3GPP LTE specification employs rate matching to support the Quality of Service (“QoS”) requirements of multiple transport channels.

FIG. 1 shows a block diagram of the transmitter transport flow of system 100 in accordance with the 3GPP LTE specification (3GPP TS 36.212 V8.3.0, Section 5.1.4, pp 15-20, which is incorporated herein by reference). Encoder 102 generates a bit sequence that is split into three sub-blocks: systematic sub-block 120, parity1 sub-block 122, and parity2 sub-block 124. Each sub-block is provided to an interleaving block, shown as sub-block interleavers 104, 106 and 108. Sub-block interleavers 104, 106 and 108 function as described in section 5.1.4 of the 3GPP TS. Within sub-block interleavers 104, 106 and 108, dummy bits are inserted at the beginning of each column of each sub-block, shown as dummy bits 130, 132 and 134. Dummy bits are inserted to pad the columns of the sub-blocks such that each column of each sub-block contains an equal number of bits. Next, the columns of each sub-block, including the dummy bits, are permuted according to the relationship defined in section 5.1.4 of the 3GPP TS, and the data in each sub-block, including the dummy bits, is read out, column by column, to provide interleaved output bits. Thus, sub-block interleavers 104, 106 and 108 provide interleaved systematic sub-block (“Vsys”) 140, interleaved parity1 sub-block (“Vp1”) 142, and interleaved parity2 sub-block (“Vp2”) 144, respectively.

Each of the interleaved sub-blocks Vsys 140, Vp1 142 and Vp2 144 is provided to Bit Collector 110. Bit Collector 110 provides collected bits block (“Wk”) 150 by first inserting bits of Vsys sub-block 140, and then interleaving bits of Vp1 142 and bits of Vp2 144. Bits of Vp1 142 and bits of Vp2 144 are interleaved such that the first bit is collected from Vp1 142, the second bit is collected from Vp2 144, and so on, until all the bits have been interleaved into block Wk 150.

Block Wk 150 is provided to Bit Selector 112. Bit Selector 112 selects the physical bits to be transmitted (“Ek”) 160. Bit Selector 112 is necessary because the number of valid bits in block Wk 150 may exceed the number of bits available in the physical layer of the transport channel and because block Wk 150 includes dummy bits. For example, to support the maximum data rate of the 3GPP LTE specification, as many as 60% of the valid bits are not selected for the physical layer. Thus, at the maximum data rate, only 40% of valid bits are selected and transmitted, but 100% of the valid bits have been interleaved by the sub-block interleavers 104, 106 and 108 and collected by Bit Collector 110.

Bit Selector 112 sequentially reads bits from block Wk 150 until the number of selected bits is equal to the number of bits available in the physical layer. The bits in block Wk 150 include dummy bits, and as bits are sequentially read in, each bit must be checked to determine whether it is a valid bit or a dummy bit, as only valid bits need be selected and transmitted. Dummy bits are not selected to be transmitted and are pruned. Valid hits are provided as Ek 160 and are provided to the physical layer.

FIG. 2 shows a block diagram of method 200 that may be employed by system 100 of FIG. 1. At step 202, dummy bits are added to each column of the systematic, parity1 and parity2 sub-blocks. At step 204, each of the sub-blocks is interleaved by a two-stage process by first permuting the columns of each sub-block. Next, at step 206, the sub-blocks are further interleaved by being read out column-by-column. Thus, as indicated by dashed block 218, steps 202, 204 and 206 are collectively performed for each sub-block by, for example, sub-block interleavers 104, 106 and 108. As the bits of the sub-blocks are read-out, they are collected at step 208, which, for example, is performed by Bit Collector 110 of FIG. 1. All the bits of the sub-blocks are interleaved and collected, including dummy bits.

At step 210 a bit from the collected bit is read and an index pointer is incremented to point to the next bit. Thus, at step 212, a test determines on a bit-by-bit basis whether each collected bit is a valid bit or a dummy bit. If the test of step 212 determines the bit is not a valid bit (i.e. a dummy bit), the dummy bits are not selected and the next bit is read at step 210. If the test of step 212 determines the bit is a valid bit, the bit is sent to the physical layer at step 214. At step 216, a test determines if the maximum number of bits supported by the physical layer has been selected. If the test of step 216 determines the maximum number of bits has not been selected, then the next bit is read at step 210. If the test of step 216 determines the maximum number of bits available for the physical layer has been reached, any remaining valid bits are not selected and the process is ended at step 217. As indicated by dashed block 220, steps 210, 212, 214, 216 and 217 are collectively performed, for example, by Bit Selector 112 of FIG. 1.

### SUMMARY OF THE INVENTION

In an exemplary embodiment, the present invention provides for rate matching with an encoded sequence of data bits. The encoded sequence of data bits is divided into two or more sub-blocks, with each of the sub-blocks having at least one column of bits. Each column of bits includes a set of valid bits. A set of dummy bits is generated and is appended to each column of each sub-block. A starting point index for the set of valid bits within each sub-block is generated and the number of bits supported by the physical layer is determined. Only the valid bits of each sub-block are interleaved, based on each starting point index, until either i) there are no valid bits remaining, or ii) the number of interleaved bits reaches the number of bits supported by the physical layer. All dummy bits and any valid bits in excess of the number of bits supported by the physical layer are omitted.

### BRIEF DESCRIPTION OF THE DRAWINGS

Other aspects, features, and advantages of the present invention will become more fully apparent from the following detailed description, the appended claims, and the accompanying drawings in which like reference numerals identify similar or identical elements.

FIG. 1 shows a block diagram of a transmitter transport flow of a rate-matching system in accordance with the prior art;

FIG. 2 shows a process diagram of the system shown in FIG. 1;

FIG. 3 shows a block diagram of a transmitter transport flow of a rate-matching system in accordance with an exemplary embodiment of the present invention;

FIG. 4 shows an exemplary sub-block of bits after dummy bits are appended;

FIG. 5 shows a process diagram of the system shown in FIG. 3; and,

FIG. 6 shows a block diagram of a receiver transport flow of a de-rate-matching system in accordance with an embodiment of the present invention.

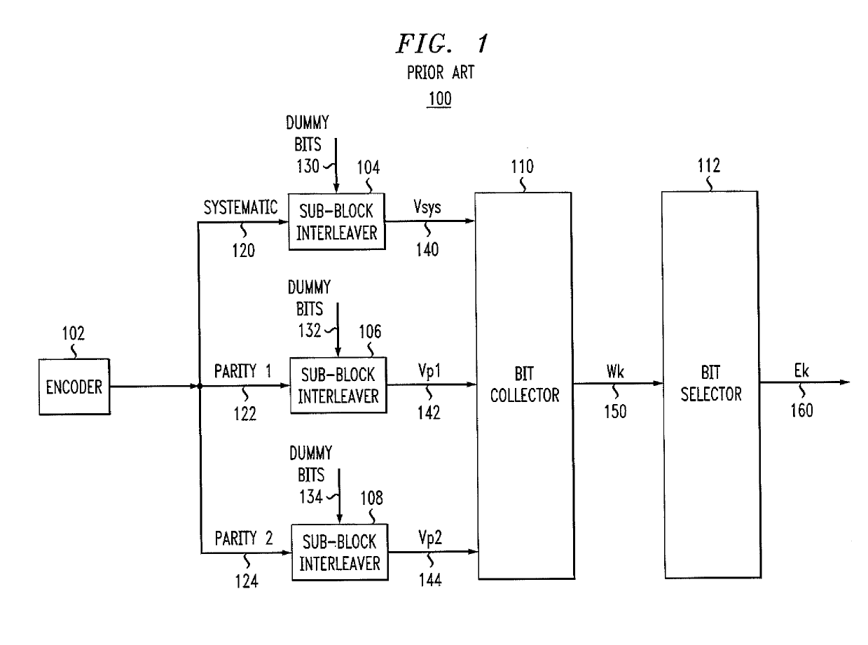

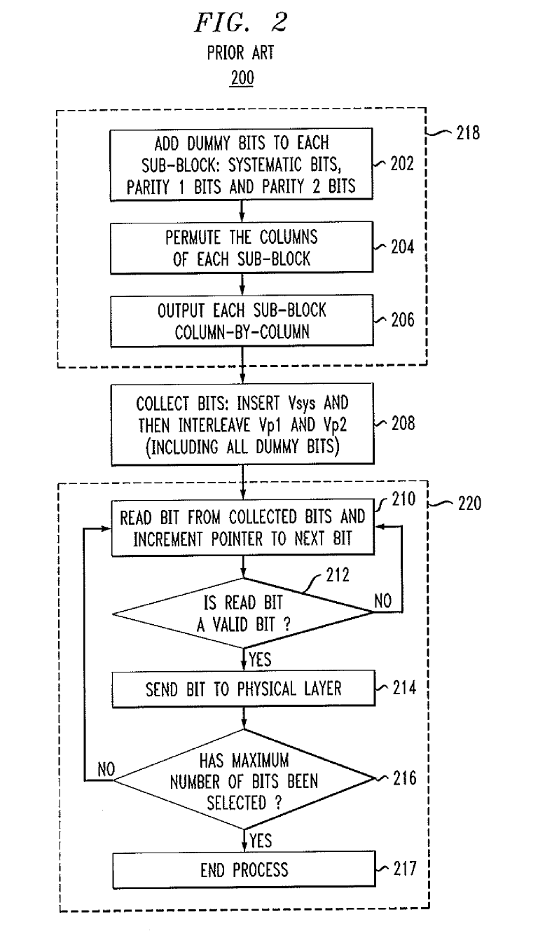

### DETAILED DESCRIPTION

Embodiments of the present invention provide rate matching and interleaving for an LTE transport channel. The present invention requires fewer processor operations than prior art rate matching, as will be described below.

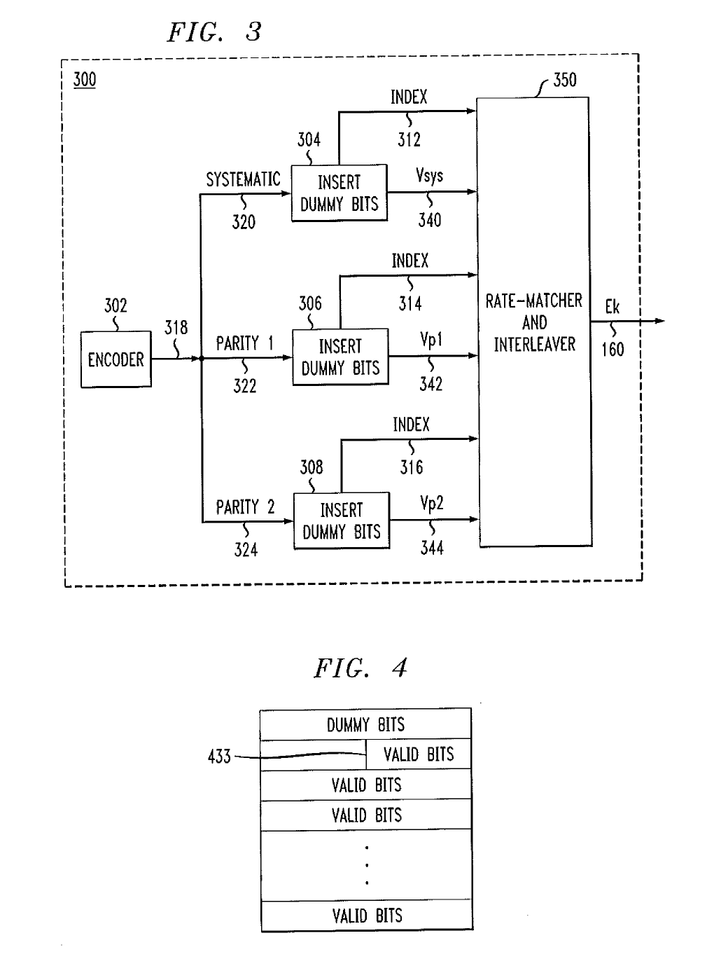

FIG. 3 shows a block diagram of a transmitter transport flow of rate-matching system 300 in accordance with an embodiment of the present invention. Encoder 302 generates bit sequence 318, which is split into three sub-blocks: systematic sub-block 320, parity1 sub-block 322, and parity2 sub-block 324. In an exemplary embodiment, dummy bits are appended to the beginning of the systematic, parity1 and parity2 sub-blocks at blocks 304,306 and 308, respectively. FIG. 4 shows an exemplary sub-block having dummy and valid bits. As shown in FIG. 4, the dummy bits are inserted at the beginning of the sub-block. Thus, the columns of the sub-block contain dummy bits at the beginning of each column, although the number of dummy bits in each column might not be equal, and some columns might contain zero dummy bits. In this way, the number of dummy bits in each column of each sub-block are predetermined, thus, an index 433 corresponding to the location of the first valid bit in each column of each sub-block might be determined. Thus, referring back to FIG. 3, indices 312, 314 and 316 corresponding to the location of the first valid bit in each column of each sub-block may be determined for each column of the systematic, parity1 and parity2 sub-blocks, respectively. Systematic, parity1 and parity2 sub-blocks with dummy bits appended are shown as Vsys 340, Vp1 342 and Vp2 344, respectively. Vsys 340, Vp1 342 and Vp2 344 are provided to rate-matcher and interleaver 350. The indices 312, 314 and 316 are also provided to rate-matcher and interleaver 350.

In one exemplary embodiment, indices 312, 314, and 316 may be determined for all of the columns of each sub-block at the same time, and, thus, might be an array of indices. Alternatively, indices 312, 314, and 316 may be determined as necessary on a column-by-column basis as each column of the respective sub-block is interleaved, as will be discussed in greater detail below. Moreover, indices 312, 314, and 316 may be determined prior to, during, or after insertion of the dummy bits. In an exemplary embodiment, each sub-block has 32 columns.

Within rate-matcher and interleaver 350, the columns of each sub-block, including dummy bits, are permuted according to the relationship defined in section 5.1.4.1.1 of the 3GPP TS, and the data in each sub-block, excluding dummy bits, is read out, column by column, according to a predefined permutation table. Dummy bits are omitted from the output bits by skipping to the starting locations indicated by starting indices 312, 314 and 316 for the valid bits for the current column of each respective sub-block. For example, the permutation relationship for the systematic and parity1 sub-blocks is predefined by the 3GPP TS as follows: <0, 16, 8, 24, 4, 20, 12, 28, 2, 18, 10, 26, 6, 22, 14, 30, 1, 17, 9, 25, 5, 21, 13, 29, 3, 19, 11, 27, 7, 23, 15, 31>, where the numbers correspond to the column number of the sub-block. Thus, for the systematic and parity1 sub-blocks, the first column to be read out is column 0, the second column to be read out is column 16, and so on. The permutation relationship for the parity2 sub-block is defined in the 3GPP TS by a formula, which after simplification becomes: parity2 permutation=(parity1 permutation+1) modulo(32). Thus, for the parity2 sub-block, the first column to be read out is column 1, the second column to be read out is column 17, and so on, with column 0 being the last column to be read out for the parity2 sub-block.

Thus, in one exemplary embodiment, index 312 is determined so as to point to the first valid bit in each column of the systematic sub-block Vsys 340, index 314 is determined so as to point to the first valid bit in each column of parity1 sub-block Vp1 342 and index 316 is determined so as to point to the first valid bit in each column of parity2 sub-block Vp2 344. In an alternative exemplary embodiment, indices 312, 314 and 316 are determined for the columns within each respective sub-block on a column-by-column basis before interleaving of each respective column begins.

Rate-matcher and interleaver 350 continues to read out valid interleaved output bits, Ek 160, as described above until the maximum number of bits available in the physical layer has been reached or until there are no more valid bits. If there a fewer valid bits than the maximum number of bits in the physical layer, previously read out valid bits will be duplicated until the maximum number of bits available in the physical layer is reached. Once the number of bits included in output bits Ek 160 is equal to the maximum number of bits available in the physical layer, any remaining valid bits are not interleaved, are not sent to the physical layer, and are discarded. Valid bits Ek 160 are thus rate-matched for the physical layer and are provided to the physical layer for transmission. Many processor cycles are saved by excluding dummy bits and non-selected bits from the rate-matching and interleaving process.

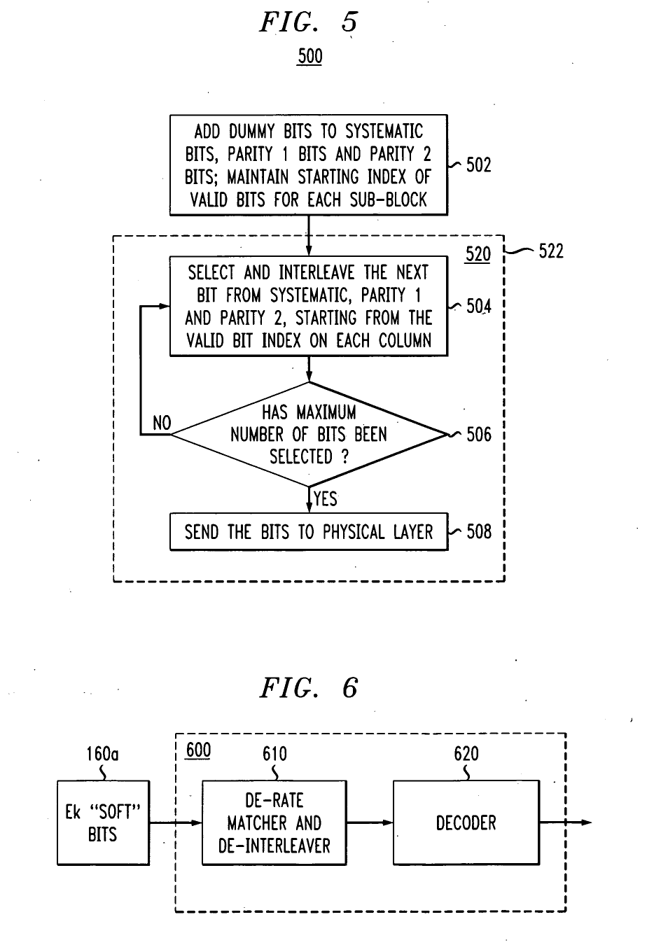

FIG. 5 shows a block diagram of method 500 that may be employed by the rate-matching system 300 of FIG. 3. At step 502, dummy bits are added to each of the systematic, parity1 and parity2 sub-blocks and starting indices for the valid bits are maintained for each sub-block. At step 504, the columns of the sub-block, including dummy bits, are permuted according to the relationship defined in section 5.1.4 of the 3GPP TS, and the valid bits of the systematic, parity1 and parity2 sub-blocks are read out, column by column according to the permutation, to provide valid output bits, Ek 160. Dummy bits are omitted from the output bits by skipping to the starting index for the valid bits for each respective column of each sub-block. Thus, at step 504, the columns of the sub-blocks are permuted according to the predefined permutation table and the valid bits of the parity1 and parity2 sub-blocks are interleaved together.

Rate-matcher and interleaver 350 continues to read out valid interleaved output bits, Ek 160 as described above until the maximum number of bits available in the physical layer has been reached at step 506. Because no dummy bits are included, all of the interleaved output bits are valid, and thus all of the interleaved output bits may be provided to the physical layer at step 508 until the maximum number of bits available in the physical layer is reached. Once the number of bits included in output bits Ek 160 is equal to the number of bits in the physical layer, any remaining valid bits are not interleaved and are not provided to the physical layer. Many processor cycles are saved by excluding dummy bits and non-selected bits from the rate-matching and interleaving process. As indicated by dashed block 522, steps 504, 506 and 508 collectively form rate-matching and interleaving process 520, which is performed by rate-matcher and interleaver 350 of FIG. 3.

FIG. 6 shows a block diagram of a receiver transport flow system 600 in accordance with an embodiment of the present invention. For example, the physical layer of system 300 of FIG. 3 might communicate valid bits Ek 160 over a transmission medium to a de-rate matcher and decoder as shown in FIG. 6. For example, when valid bits Ek 160 are transmitted wirelessly, the bits received might not be identical to the transmitted bits Ek 160 due to noise, and are thus denoted as soft bits Ek 160a. De-rate matcher and de-interleaver 610 receives soft bits Ek 160a and de-rate matches and de-interleaves the bits of Ek 160 in an inverse manner to the rate-matching and interleaving process previously described. Decoder 620 decodes the de-rate matched and de-interleaved bits in an inverse manner to that of Encoder 302. Decoder 620 also performs an error correction process on the de-interleaved sequence of bits to reconstruct the original bit sequence. As shown, system 600 is configured to provide the reconstructed original bit sequence for further processing.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

While the exemplary embodiments of the present invention have been described with respect to processes of circuits, including possible implementation as a single integrated circuit, a multi-chip module, a single card, or a multi-card circuit pack, the present invention is not so limited. As would be apparent to one skilled in the art, various functions of circuit elements may also be implemented as processing blocks in a software program. Such software may be employed in, for example, a digital signal processor, micro-controller, or general-purpose computer.

The present invention can be embodied in the form of methods and apparatuses for practicing those methods. The present invention can also be embodied in the form of program code embodied in tangible media, such as magnetic recording media, optical recording media, solid state memory, floppy diskettes, CD-ROMs, hard drives, or any other machine-readable storage medium, wherein, when the program code is loaded into and executed by a machine, such as a computer, the machine becomes an apparatus for practicing the invention. The present invention can also be embodied in the form of program code, for example, whether stored in a storage medium, loaded into and/or executed by a machine, or transmitted over some transmission medium or carrier, such as over electrical wiring or cabling, through fiber optics, or via electromagnetic radiation, wherein, when the program code is loaded into and executed by a machine, such as a computer, the machine becomes an apparatus for practicing the invention. When implemented on a general-purpose processor, the program code segments combine with the processor to provide a unique device that operates analogously to specific logic circuits. The present invention can also be embodied in the form of a bit stream or other sequence of signal values electrically or optically transmitted through a medium, stored magnetic-field variations in a magnetic recording medium, etc., generated using a method and/or an apparatus of the present invention.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

As used herein in reference to an element and a standard, the term “compatible” means that the element communicates with other elements in a manner wholly or partially specified by the standard, and would be recognized by other elements as sufficiently capable of communicating with the other elements in the manner specified by the standard. The compatible element does not need to operate internally in a manner specified by the standard.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

We claim:

1. A method for rate matching with an encoded sequence of data bits, the method comprising:
a) dividing the encoded sequence of data bits into two or more sub-blocks, each of the sub-blocks having at least one column, and the at least one column of each sub-block having a set of valid bits;
b) generating i) a set of dummy bits appended to each sub-block, and ii) a starting point index for the set of valid bits within each sub-block;
c) determining a number of bits supported by a physical layer;
d) rate-matching by interleaving, based on each starting point index, only the valid bits of each sub-block until either i) until there are no valid bits remaining, or ii) the number of rate-matched and interleaved bits reaches the number of bits supported by the physical layer; and
e) omitting, based on each starting point index, all dummy bits and any valid bits in excess of the number of bits supported by the physical layer.

2. The invention of claim 1, wherein step d) further comprises:
if there are valid bits remaining and the number of rate-matched and interleaved bits has not reached the number of bits supported by the physical layer, duplicating previous valid bits until the number of rate-matched and interleaved bits reaches the number of bits supported by the physical layer.

3. The invention of claim 1, further comprising the step:
f) providing the rate-matched and interleaved set of valid bits to the physical layer.

4. The invention of claim 1, wherein the encoded sequence of data bits is split into three sub-blocks comprising a systematic sub-block, a parity1 sub-block and a parity2 sub-block.

5. The invention of claim 4, wherein each sub-block comprises 32 columns.

6. The invention of claim 1, wherein, for step a), each starting point index is determined for each column within the sub-block for each respective sub-block.

7. The invention of claim 6, wherein the starting point index for each column within the sub-block is determined on a column-by-column basis before hits from the column are rate-matched and interleaved in step d).

8. The invention of claim 4, wherein step d) further comprises
i) permuting the columns of at least one sub-block;
ii) reading out the set of valid bits of the systematic sub-block column by column according to the permutation; and,
iii) reading out the set of valid bits of the parity1 sub-block and the parity2 sub-block column by column, according to the permutation, to provide valid interleaved output bits.

9. The invention of claim 8, wherein for step d)(i), the columns of the systematic and parity1 sub-blocks are permuted by a predefined permutation table where the columns are permuted in the order <0, 16, 8, 24, 4, 20, 12, 28, 2, 18, 10, 26, 6, 22, 14, 30, 1, 17, 9, 25, 5, 21, 13, 29, 3, 19, 11, 27, 7, 23, 15, 31>.

10. The invention of claim 9, wherein the columns of the parity2 sub-block are permuted by the relationship: parity2 column=(parity1 column+1) modulo(32).

11. The invention of claim 1, wherein step b) further comprises the step of:
i) maintaining the starting point index of valid bits of the column of each sub-block that is presently being rate-matched and interleaved in step d); and
ii) maintaining the starting point index of valid bits of the column of each sub-block that is next interleaved in step d).

12. An apparatus for rate matching with an encoded sequence of data bits, comprising:
a) a splitter to divide the encoded sequence of data bits into two or more sub-blocks, each of the sub-blocks having at least one column, and the at least one column of each sub-block having a set of valid bits;
b) a generator in communication with the splitter configured to i) generate and append a set of dummy bits to each column of each sub-block, and ii) determine a starting point index for the set of valid bits within each sub-block;
c) a rate-matcher having an interleaver, coupled to and in communication with a physical layer and the generator, wherein the generator provides to the rate-matcher the starting point index for the set of valid bits within each sub-block, and wherein the generator provides to the rate-matcher each sub-block, including valid and dummy bits, and wherein the rate-matcher may determine the number of bits supported by the physical layer, whereby the rate-matcher, based on each starting point index, only interleaves the valid bits of each sub-block until either i) until there are no valid bits remaining, or ii) the number of interleaved bits reaches the number of bits supported by the physical layer and whereby the rate-matcher does not select all dummy bits and any valid bits in excess of the number of bits supported by the physical layer.

13. The invention of claim 12, wherein if there are valid bits remaining and the number of rate-matched and interleaved bits has not reached the number of bits supported by the physical layer, the rate-matcher will duplicate previous valid bits until the number of rate-matched and interleaved bits reaches the number of bits supported by the physical layer.

14. The invention of claim 12, wherein the splitter divides the encoded sequence of data bits into three sub-blocks comprising a systematic sub-block, a parity1 sub-block and a parity2 sub-block.

15. The invention of claim 12, wherein each sub-block comprises 32 columns.

16. The invention of claim 12, wherein the rate-matcher further comprises a circuit to permute the columns of at least one sub-block, and wherein the rate-matcher provides the set of valid bits of the systematic sub-block column by column according to the permutation, and the set of valid bits of the parity1 sub-block and the parity2 sub-block column by column according to the permutation, to provide valid interleaved output bits.

17. The invention of claim 16, wherein the columns of the systematic and parity1 sub-blocks are permuted by a predefined permutation table where the columns are permuted in the order <0, 16, 8, 24, 4, 20, 12, 28, 2, 18, 10, 26, 6, 22, 14, 30, 1, 17, 9, 25, 5, 21, 13, 29, 3, 19, 11, 27, 7, 23, 15, 31>.

18. The invention of claim 17, wherein the columns of the parity2 sub-block are permuted by the relationship: parity2 column=(parity1 column+1) modulo(32).

19. The invention of claim 12, wherein the generator maintains the starting point index of valid bits of the column of each sub-block that is presently being interleaved by the interleaver, and also maintains the starting point index of valid bits of the column of each sub-block that is next interleaved by the interleaver.

20. A method for de-interleaving and decoding a sequence of rate-matched bits, wherein the sequence of rate-matched bits is encoded by a) dividing the encoded sequence of data bits into two or more sub-blocks, each of the sub-blocks having at least one column, and the at least one column of each sub-block having a set of valid bits; b) generating i) a set of dummy bits appended to each column of each sub-block, and ii) a starting point index for the set of valid bits within each sub-block; c) determining a number of bits supported by a physical layer; d) interleaving, based on each starting point index, only the valid bits of each sub-block until either i) until there are no valid bits remaining, or ii) the number of interleaved bits reaches the number of bits supported by the physical layer; and e) omitting, based on each starting point index, all dummy bits and any valid bits in excess of the number of bits supported by the physical layer, the de-interleaving and decoding method comprising:
a) receiving a rate-matched sequence of bits;
b) de-rate matching and de-interleaving the rate-matched sequence of bits to provide a de-rate matched and de-interleaved sequence of bits; and
c) decoding and performing an error correction process on the de-rate matched and de-interleaved sequence of bits to reconstruct an original bit sequence.
